(19) United States
(12) Patent Application Publication
(10) Pub. No.: US 2002/0012749 A1
(43) Pub. Date: Jan. 31, 2002

(54) Method and apparatus for coating and/or treating substrates

(76) Inventors: Hilmar von Campe, Bad Homburg (DE); Dieter Nikl, Kelkheim (DE); Horst Ebinger, Salmunster (DE); Stephan Will, Wetzlar (DE); Torsten Buschbaum, Sargans (CH)

Correspondence Address: DENNISON, SCHEINER SCHULTZ & WAKEMAN, 612 CRYSTAL SQUARE FOUR, 1745 JEFFERSON DAVIS HIGHWAY, ARLINGTON, VA, 22202-3417, US

(21) Appl. No.: 09/821,763

(22) Filed: Mar. 30, 2001

(30) Foreign Application Priority Data
Apr. 6, 2000 (DE) 100 16 971.6

(51) Int. Cl. C23C 16/00; B05D 3/02

(52) U.S. Cl. 427/314; 427/248.1; 118/715; 427/180

(57) ABSTRACT

The present invention relates to a method and an apparatus for coating and/or treating a surface of a substrate by applying to the surface a gas containing coat-forming particles necessary for coating, the particles being deposited on and/or reacting with the surface. In order to coat substrate surfaces to the desired extent or to treat them by reaction with gases, in particular using CVD processes, it is proposed to separate out the gas into partial flows tuned with respect to their particle concentrations and/or dwell time on the surface or directly adjacent to the surface of the substrate in such a way that equal amounts of particles are deposited and/or reacted per surface unit and time unit

The present invention relates to a method for coating a surface of a substrate by applying to said surface a gas comprising coat-forming particles necessary for coating, the particles being deposited on and/or reacting with said surface. The invention further relates to an apparatus for coating and/or treating a surface of a substrate by applying a gas to said surface, comprising a plurality of gas-emitting sources as well as gas sinks for gas having reacted with or having been applied to the substrate.

A variety of principles may be utilized for coating substrates or surfaces using a CVD (chemical vapor deposition) process. One approach would be to have a gas flow parallel to the substrate surface, the substrate being either fixed or moving. When the gas is passing along the substrate surface, there is a tendency for the carrier gas to be quickly depleted. With a fixed substrate, non-uniform deposition rates, non-uniform film thicknesses as well as irregular dopings in the direction of the coating thickness and coating surface can also be observed.

While a moving substrate would allow a uniform film thickness to be achieved, it leads to a non-uniform deposition rate. Also, irregular doping call be observed in the direction of the film thickness.

In target-flow reactors, the gas to be applied to a substrate surface flows from above onto the substrate in a vertical direction. A uniform deposition rate can be achieved with substrates of a limited size. A certain uniformity can also be observed in the coating thickness and doping in the direction of the film thickness and in the direction of the film surface. However, there are problems with removing reacted gas when coating large surfaces, so that good results can only be achieved on relatively small substrate surfaces in the case of target-flow reactors.

For achieving uniform depositions on large surfaces, pancake reactors are used that work on a similar principle to the target-flow reactor. This means that the gas flows in a vertical direction onto the surface to be coated. The substrate itself is arranged on a hot substrate pedestal so that the resulting convection in the gas atmosphere allows the gas to be mixed and homogenized this results in uniform deposition rates, uniform film thicknesses as well as uniform dopings in the direction of the film thickness and surface. Uniformity can also be enhanced by rotating the substrate pedestal during the coating process. Although such a coating process is useful for coating large surfaces and results in reproducible, high-grade epitaxial layers, a drawback is that the gas intake is from the center of the system through a disk and its usefulness is therefore limited to the coating of wafers.

Such a method, or reactors used for implementing it, can be found in the cited US publication entitled: “Chemical Vapor Deposition for Microelectronics”, Arthur Sherman, Noyes Publications, USA, pp. 31-39, 150-174.

The problem underlying the present invention is to further develop a method and an apparatus of the type mentioned at the outset in such a way that substrate surfaces are able to be coated or to be treated by reacting them with gases to the desired extent, in particular using CVD processes. Industrial scale treatment or coating of surfaces should also be made possible.

In accordance with the invention, the object is solved using a method of the type mentioned at the outset by separating out the as into partial gas flows whose particle concentration and/or dwell time directly in the region of the surface and/or on the surface of the substrate can be tuned in such a way that equal amounts of constituents can be deposited and/or reacted per surface unit and per time unit. The dwell time can be tuned by a relative movement or speed between the substrate and the sources emitting the partial flows. In particular, the gas partial flows are emitted toward the surface by a plurality of sources, with as sinks arranged between them for gas that has reacted with and/or been applied to, the substrate. The expression “directly in the region of the surface” here means the space between the emission points of the gas partial flows and the surface(s) to be treated.

The partial flows themselves are applied to the surface in a bottom-up direction while the sources and/or the sinks are arranged in a regular pattern across and below such surface. The necessary heating of the substrates and hence of the surface to be coated/treated is done in particular on the surface facing away from the gas.

During the treatment or coating of the surface itself, the substrate should be moved in a direction perpendicular to the gas flow so that continuous processing is possible, which is particularly suitable for substrates having large surfaces, i.e. for large surfaces in general. Arranging the sinks in a regular pattern below the surface to be coated/treated as well as between the sources emitting the partial gas flows ensures that equal amounts of constituents ale deposited from the gas and/or react with the surface per surface unit and per time unit, so that uniform deposition rates, uniform film thicknesses and even, i.e. uniform, doping can be achieved in the direction of the film thickness as well as in the direction of the plane defined by the surface. There is no uncontrolled depletion of the gas, also called carrier or nutrient gas, containing the particles for reacting with or for treating the surface.

An apparatus for coating and/or treating a surface of a substrate, in particular using CVD processes, comprising a plurality of gas-emitting sources as well as gas sinks for said gas having reacted with or having been applied to said substrate is characterized in that the surface of the substrate is arranged above the sources and sinks and in that the sources are distributed over a region in a regular pattern, said region being defined by a vertical projection of the surface of the substrate, with the sinks preferably being arranged between said sources in a regular pattern. In particular, the sources and sinks form a gas distribution system whose surface extension is at least equal to or substantially at least equal to the surface of the substrate itself.

The sources emitting the carrier or nutrient as can comprise or be designed as slots, nozzles or other openings through which the gas can be emitted in a vertical direction or in a substantially vertical direction rising firm the bottom up toward the surface of the substrate.

The sources can be arranged in a first plane parallel to the surface and the sinks can be arranged in a second plane parallel to the surface, where the first and second planes may be at a distance from one another. Preferably, in such an embodiment, the first plane comprising the sources should be closer to the surface than the second plane comprising the sinks.

In a further embodiment of the invention it is envisaged that the sources, such as openings, slots or nozzles, communicate with a space containing uniformly distributed as. The space itself can be a cube or a hollow cylinder, such as a tube. The “space” can also mean a plurality of hollow cylinders or tubes.

When tubes are used such tubes should be arranged parallel to each other below the surface of the substrate with the sources as well as the sinks, in particular slots, being arranged along cach longitudinal axis of each tube. The slot longitudinal axes and the longitudinal axis of the tube would then be parallel.

The gas distribution system itself can be arranged inside the reactor chamber, with the surface of the substrate closing off or defining the chamber. In particular, the substrate is intended to be aligned with the reactor chamber by means of guide rails the reactor chamber being able to be sealed by means of the substrate and the guide rails.

The necessary heating sources, such as radiation heaters and/or microwave radiators, can be arranged above the substrate on the substrate surface facing away from the gas distribution system.

In particular, it is envisaged to house the reaction chambers themselves inside a chamber in order to permit successive treatment or coating of the substrate surface, the reactor chambers being able to contain a variety of nutrient or carrier gases. The chamber arrangement is a continuous processing system, the reactor chambers present within it for successive coating, or treatment of the surface being able to be sealed by the substrate or the surface, The chamber arrangement can be flowed through by an meet gas flowing in a flow direction opposite the direction of movement of the substrate.

Further details, features and advantages of the invention can be seen not only from the claims and the features to be derived from them—singly and/or in combination—but also from the following description of the preferred embodiment taken in conjunction with the accompanying drawing in which:

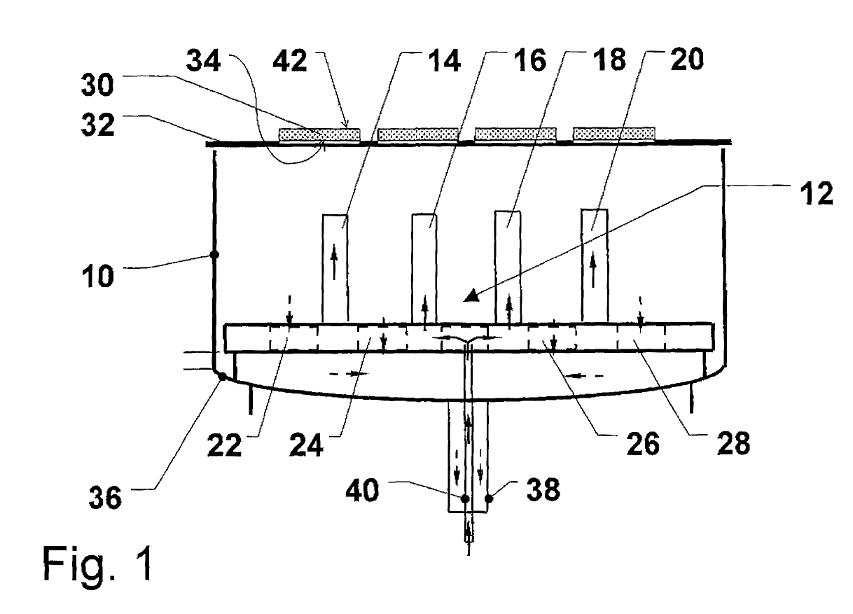

FIG. 1 shows a first arrangement for coating a substrate.

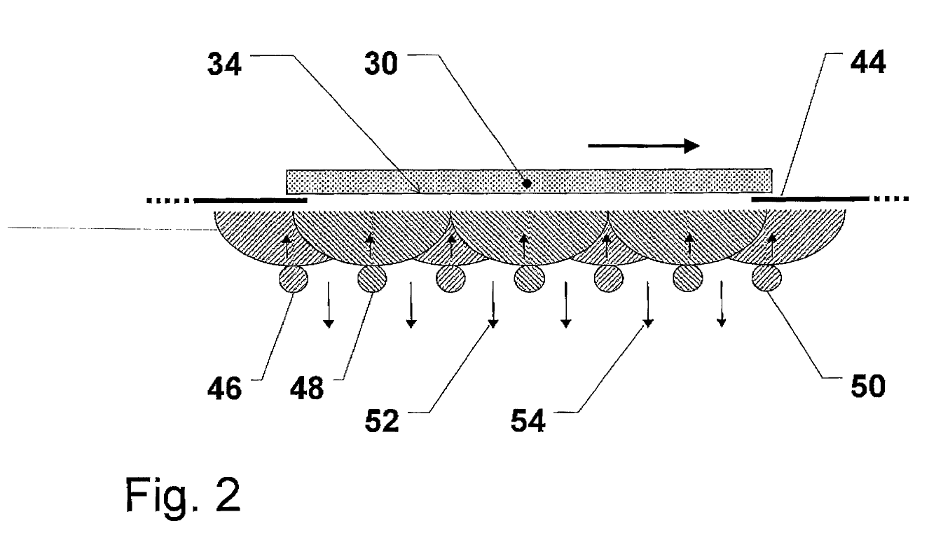

FIG. 2 shows a sectional view of a second embodiment of an arrangement for coating a substrate.

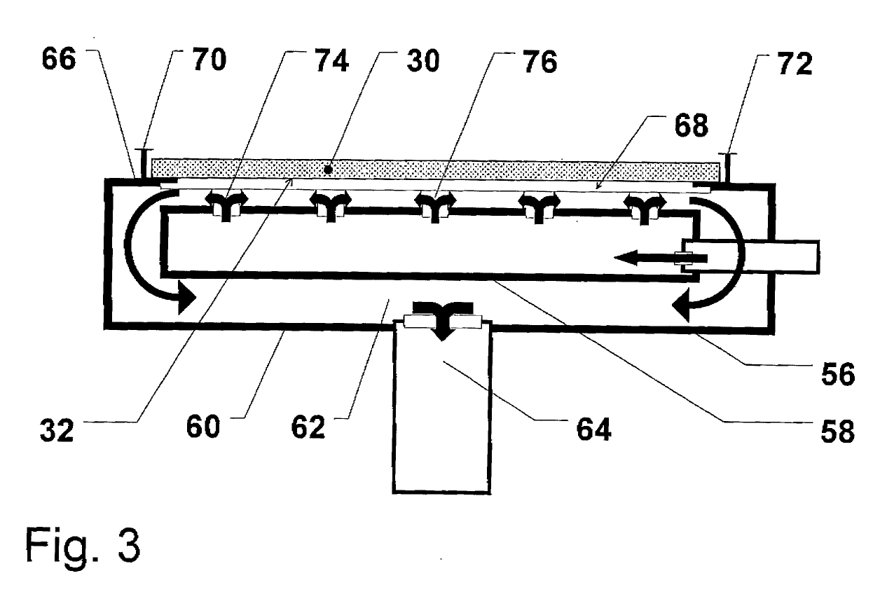

FIG. 3 shows the principle of a third embodiment of an arrangement for coating a substrate, and

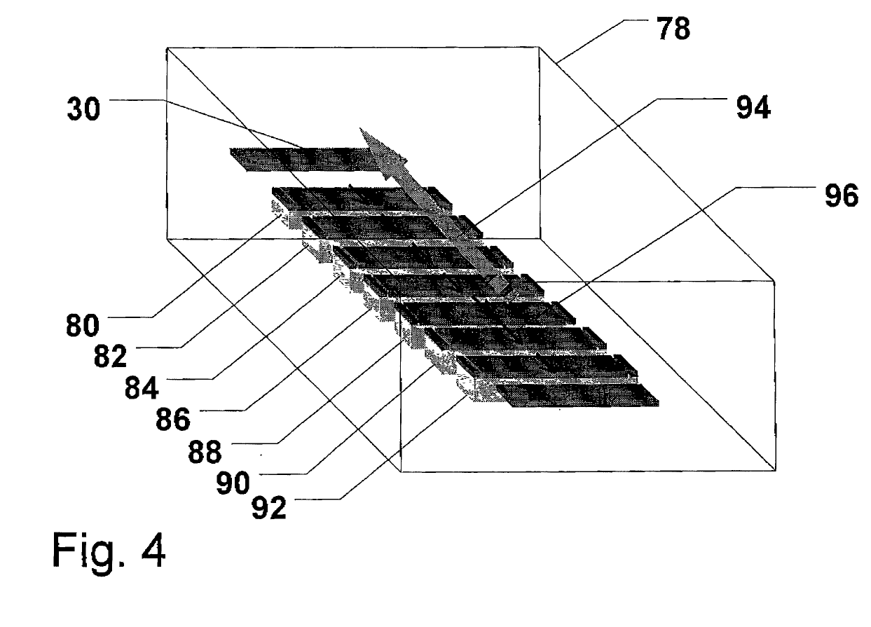

FIG. 4 shows the principle of a continuous processing arrangement.

For providing substrates such as those of semiconductor components such as thin film solar cells with desired coatings or for forming such coatings on the substrate, CVD processes are usually applied. The substrate is treated with a carrier or nutrient gas containing coat-forming particles deposited on the surface or reacting with the latter. In accordance with the invention, it is provided that to separate out the nutrient or carrier gas are separated out into partial flows in such a way that equal amounts of particles are deposited on and/or react with the surface with respect to the particle concentration in the partial flows and/or the dwell time on the surface per surface unit and per time unit.

With reference to FIG. 1, an apparatus is shown comprising a reactor 10, in which a gas distribution system 12 is arranged comprising gas sources 14, 16, 18, 20 as well as gas sinks 22, 24, 26, 28. The gas sources 14, 16, 18, 20 through which the nutrient or carrier gas is separated out into partial flows are designed as flues or hollow cylindrical elements arranged with their openings below substrates 30 to be coated, the substrates themselves being arranged above The reactor 10 being closed by a mask 32 having an opening or a plurality of openings on which, in the present embodiment, a plurality of substrates 30 comprising surfaces 34 to be coated are aligned in a row.

The gas sources 14, 16, 18, 20 are regularly distributed across the surfaces 34 defined by the substrates 30 and arc arranged in a plane which is closer to the surface than the gas sinks 22, 24, 26, 28 with their evacuation openings. The sinks 22, 24, 26, 28 are used to evacuate as that has reacted with the surfaces 34. The sinks 22, 24, 26, 28 are also regularly distributed across the plane defined by the substrate surfaces 34 An evacuation pipe 38 for evacuating, reacted gas projects from the bottom 36 of the reactor 10 arid has a gas inlet pipe 40 arranged inside it, providing carrier or nutrient as to the gas sources 14, 16, 18, 20 formed as flues or hollow cylinders.

By evenly distributing the gas a cross the plane defined by the surfaces 34 to be coated and also by distributing the sinks 22, 24, 26, 28 evacuating the reacted gas across the plane and between the sources 14, 16, 18, 20, and by having the gas itself reach the surfaces 34 of the substrates 30 rising vertically from below, a uniform deposition with—at the same time—a uniform film thickness and a uniform doping both in the direction or the film thickness and in the plane defined by the surface 34.

Insofar as heating of the surfaces 34 is necessary for the coating process, the substrates 30 are provided for example with heat radiation or microwaves an the surface 42 facing away from the gas sources 14, 16, 18, 20. By evenly distributing the gas sources 14, 16, 18, 20, i.e. the gas supply, across the plane defined by the surfaces 34, and by having the gas to be applied to the surfaces 34 rise vertically, while the surface defined by the gas sources 14, 16, 18, 20 and the gas sinks 22, 24, 26, 28 is equal to or greater than the entirety of the surfaces 34 to be coated, a uniform gas distribution is achieved, ensuring a reproducible and desired uniform deposition and hence film thickness and doping. Moreover, the substrates 30 may be moved in a direction perpendicular to the gas flow to further improve uniformity.

With reference to FIG. 2 a further embodiment of the arrangement for coating a surface 34 of a substrate 30 is shown, the substrate being movable along the opening 44 of a reactor (not shown). In the reactor itself, gas distribution tubes 46, 48, 50 are arranged parallel to one another, between which gas having reacted with the surface 34 is evacuated (arrows 52, 54). This arrangement also ensures an even distribution of the gas sources and sinks formed by the gas distribution tubes 46, 48, 50 and the vacuum means 52, 54 respectively across the surface 34 of the substrate 30, ensuring the desired uniformity of the gas stream applied to the surface 34 and hence a uniform deposition rate, film thickness and doping. The gas distribution tubes 46, 48, 50 comprise openings such as slots or holes arranged along their longitudinal axes, through which the gas partial flows are applied to the surface 34 of the substrate 30. Preferably, slots arranged along the tubes 46, 48, 50, i.e. running parallel to their longitudinal axes, are chosen.

In the embodiment of FIG. 3, a reactor 56 is provided, inside which is a gas distribution system having a gas inlet means 58 and a gas evacuation means 60 circumferentially surrounding the gas inlet means 58 in the form of an annular slot 62 which in turn communicates with a gas outlet tube 64 in the bottom section of the reactor 56. In the top wall 66 of the reactor 56, there is an opening 68 having guide rails 70, 72 along the edges, along which the substrate 30 to be coated slides, or slides on a gas cushion at a distance from the openings. The distance may be between—for example—1 mm and 20 mm, in particular up to 10 mm, without limiting the invention. Therefore, the substrate 30 can he guided during coating in a movement relative to the emission openings 74, 76 forming the gas inlet means 58 or sources and evenly distributed below the surface 32 of the substrate 30. A kind of gas cushion is formed between the emission openings 74, 76 and the surface 32, the amounts of gas emitted from the openings 74, 76 as a function of the position of the opening 74, 76 being tuned to one another in such a way that the partial flows in respect of their particle concentration and the dwell time of the partial flows with reference to the surface 32 to be coated are tuned in such a way that equal amounts of particles are deposited on or react with the surface 32 per surface unit aid per time unit.

The pressure differential leads to the desired reproducible uniform deposition rate, film thickness and doping. Uniformity is further improved by a movement of the substrate 30 along the guide rails 70, 72 relative to the gas emission openings 74, 76. The reacted gas is evacuated on the side via the annular slot 62 and is passed through the gas outlet 64 out of the reactor 56.

Above the substrate 30, i.e. above the surface 42, a heating means such as radiation or microwave heater may be arranged to heat the substrate or to permit performance of the desired coating processes. The space outside the reactor 56 may additionally be purged with inert gas.

The gas manifold 58 itself is preferably made of quartz.

FIG. 4 is to illustrate that the method in accordance with the invention is also suitable for continuous processing. To achieve this, a sealed continuous processing chamber 78 is provided in which, one after the other, a plurality of reactors 80, 82, 84, 86, 88, 90, 92 are arranged corresponding to one of the structures described above. Each reactor 80, 82, 84, 86, 88, 90, 92 in turn is covered by a substrate 30 to be coated, in order to coat the surface facing the reactor 80, 82, 84, 86, 88, 90, 92 to the desired extent. The interior of the continuous processing chamber 78 itself may be purged by an inert gas, where the direction of flow (arrow 94) may be in the opposite direction to the transportation direction (arrow 96) of the substrate 30.

For example, a graphite substrate may be provided with an SiC layer in the first reactor 80. In the following reactor 82, a p⁺-type Si layer highly doped with boron, for example, is deposited on the SiC layer using a CVD process. A capping layer may then be deposited on the p⁺-type Si nucleation layer in the reactor 84, followed by a recrystallization process in the reactor 86. The capping layer is removed in reactor 88, to be followed by an epitaxy process of a photo sensitive p-type Si layer, and eventually in reactor 92 by the deposition of an n-conducting emitter layer

The embodiment of FIG. 4 is to illustrate that the teachings of the invention are applicable for example for the manufacture of a crystalline Si thin film system, ensuring that the films to be formed have the required uniformity, uniform thickness and doping. At the same time, each reactor 80, 82, 84, 86, 88, 90, 92 is itself sealed during processing by the substrate 30 to be treated.

Preferable process parameters are derived from the following examples:

### EXAMPLE NO. 1

An apparatus according to FIG. 1 is used to manufacture a large-area silicon film. In a tank able to be evacuated, preferably of stainless steel and having water-cooled walls (and a diameter of about 80 cm), the quartz reactor 36 is arranged having a diameter of about 70 cm. The reactor 36 is closed at its top by a carrier plate 32 having openings for receiving substrates 42 with the dimensions 0.1 m by 0.1 m, or a single opening for a substrate with the dimensions 0.4 m by 0.4 m The substrate 30 or 42 is heated through a transparent covering (e.g. a quartz window) of the tank by means of a lamp array. The space between the rank wall and the quartz reactor is constantly purged by a chemically inert gas such as argon or nitrogen. In addition, for safety reasons, this space is constantly monitored by means of an H₂ sensor to ensure that the lower explosion limit is never even reached. Heating is achieved by means of optical or infrared radiation of a radiator array having a power density of between 400 kW/m² and 700 kW/m² at temperatures of between 1100° C. and 1300° C. Alternatively, heating is achieved using microwave radiation or by inductive heating. The type of heating depends largely on the properties of the substrate. For high-absorption surfaces (gray to black colors), optical heating is suitable. Conductive substrates are suitable for heating by inductive coupling or by current flowing directly through the substrate. Ceramics having molecular dipole moment are best heated using microwaves. The process gas is a as mixture comprising hydrogen with methyl trichlorosilane (MTCS=CH₃SiHCl₃) for depositing SiC layers or trichlorosilane (TCS=SiHCl₃) for depositing Si layers. The doping of SiC is performed by adding small quantities of nitrogen (n-conducting SiC). Silicon can be doped by adding small quantities of BCl₃ to obtain a p-conducting layer.

The chemical reaction can happen at high temperatures according to the following simplified chemical reaction equations:

CH₃SiHCl₃+H₂→SiC+3 HCl (1)

SiHCl₃+H₂→Si+3HCl (2)

3 BCl₃+3H₂→2B+6HCl (3)

Distributing the gas flow is performed through a gas distribution system, preferably of quartz elements.

An MTCS/H₂ mixture is introduced to deposit SiC layers, a TCS/H₂ mixture to deposit Si layers. Each initial mixture is introduced into the manifold system via the gas pipe 40. It passes to the space between the two plates 41 and 43 and then flows through the flue-like tubes 147 16, 12, 20 towards the substrates. The substrates are at a temperature of between 1200° C. and 1550° C. for SiC deposition and of between 900° C. and 1200° C. for Si deposition so that the chemical reaction expressed by the reaction equations (1) through (3) can take place. On the substrate 30 or 42, SiC or Si is deposited respectively. The gaseous products arc forced via the sinks 22, 24, 26, 28 between the two plates 41 and 43 to the lower part of the reactor chamber, from where they can be extracted through the pipe 38. The deposition rate is in the range of 0.1 μm to 10 μm per minute. It is an exponential function of the deposition temperature of the substrate and a proportional function of the concentration of MTCS or TCS, respectively, in the process gas.

The deposition rate is critically dependent on the mol ratio of [Si]:[H] or, with MTCS, of [C+Si]:[H]. Typically this mol ratio is between 1:10 and 1:100. The yield is about 10 to 20% depending on the choice of parameters.

For examples an SiC layer having a thickness of 30 μm is deposited on a surface of 0.16 m² at a temperature of 1500° C. at a deposition rate of 5 μm/min. The gas flows are 130 slm for hydrogen, 20 slm for MTCS and 1 slm for nitrogen as a dopant gas. The mol ratio MTCS:H₂ is about 1:10.

For example, an Si layer having a thickness of 30 μm is deposited on a surface of 0.16 m² at a temperature of 1100° C. at a deposition rate of 5 μm/min. The gas flows are 200 to 2000 slm for hydrogen, 20 slm for TCS and 10 slm for a mixture of BCl₃:H₂=1:1000 as a doppant gas. The mol ratio MTCS:H₂ is about 1:100 to 1:10.

### EXAMPLE NO. 2

In the system of FIG. 2 the initial gas mixture is transported through parallel gas pipelines 46, 48, 50, preferably of quartz having bores at their top ends. The gas passes through the bores into the reaction chamber and reaches the heated substrate surface 34. The substrate 30 is moved in a parallel direction to the plane defined by the gas pipelines. This serves to improve deposition rate uniformity. The substrate is at a temperature of between 1200° C. and 1550° C. in the case of an SiC deposition and at temperatures of between 900° C. and 1200° C. in the case of an Si deposition, so that the chemical reaction expressed by the reaction equations (1) and (2) respectively can take place. SiC or Si is deposited on each respective substrate. The gaseous products 52 and 54 are extracted through spaces between the pipelines.

In a continuous processing system of FIGS. 2 to 4, the throughput can be considerably enhanced by the drive speed and the choice of the length of the plant. Since deposition rates of 5 μm/min to 10 μm/min can be achieved with the normal-pressure CVD process, only 3 to 6 min are necessary for the deposition of a CVD layer having a 30 μm thickness. By keeping the width of 40 cm and doubling the coating length to 80 cm, a surface of 0.32 m² can be manufactured in 3 to 6 minutes in a continuous process using the arrangement of FIG. 2.

### EXAMPLE NO. 3

To manufacture a large surface layer of silicon dioxide (as a capping layer for the crystallization process in the manufacture of a crystalline Si thin film solar cell) a gas nature of monosilane SiH₄ and oxygen O₂ is used as process gas. The gas is diluted with inert gas, such as nitrogen CO₂, Argon or other inert gases to avoid spontaneous nucleation, and therefore dust, in the vapor phase. The chemical reaction tales place according to the simplified chemical reaction equation

SiCl₄+2 H₂O→SiO₂+4 HCl

at temperatures of about 250° C. to 800° C., preferably at 400° C. to 450° C. The distribution of the gas flow is achieved preferably through the gas distribution system out of quartz elements. The deposition rate is in the order of 0.1 μm to 0.5 μm per minute. The coating is performed at atmospheric pressure.

The coating can also be performed in a vacuum, with the quality of the oxide layer being better, but the deposition rate lower smaller according to the particle concentration. In order to avoid pyroforic SiH₄, tetraethyl orthosilicate (C₂H₅O)4Si (TEOS) can also serve as a source of silicon. The process is carried out at 500 mbar to 1000 mbar and at temperatures of between 600° C. and 800° C., preferably 700° C.

### EXAMPLE NO. 4

For removing the large surface layer of silicon dioxide (after completion of crystallization) the surface is heated to temperatures of between 1150° C. and 1300° C. and reduced to pure hydrogen. Preferably, a temperature of 1200° C. is suitable. After complete removal of the oxide layer, the crystalline silicon layer is exposed as a nucleation layer, onto which the epitaxial Si semiconductor layer may then be deposited.

As an alternative to oxide removal through reduction with hydrogen, an H₂O/HF mixture is passed over the oxide-covered sample at temperatures ranging from room temperature to 300° C., and preferably 50° C. to 100° C. (also substrate temperature about 100° C. to 300 ° C.). A chemical reaction takes place as follows:

SiO₂+4 HF+H₂O→SiF₄+3H₂O

The compounds SiF₄ and H₂O are volatile and evaporate at these temperatures. This is why an etching effect can also be achieved at low temperatures from the vapor phase, so that the oxide layer having a thickness of 2 μm evaporates within about 10 minutes.

### EXAMPLE NO. 5

The initial mixture is introduced through a pipe into the interior 58 of a gas transportation chamber having a planar wall on the side facing the substrate 30. The gas is emitted through bores 74, 76 and passes to the heated substrate surface 32. The gaseous products can be extracted to the right and left through the gap 68 between the emission plane and the substrate. The gas is passed around the gas transportation chamber and forced out of the reaction chamber downwards through an outlet means 90 of large cross-section.

A plurality of such reaction chambers may be arranged in series, so that a continuous processing system is developed in which all layers of various composition may be deposited in succession. FIG. 4 schematically shows such a system comprising a plurality of chambers 80, 82, 84, 86, 90, 92. The chamber system is in a reaction chamber (reactor) purged with an inert gas. The substrate 30 is pre-heated in the chamber to coating temperature. The individual gas transportation chambers 80 to 100 are the following:

80: as transportation chamber for SiC coating, 82: gas transportation chamber for p⁺-type Si coating, 84: gas transportation chamber for oxide capping layer deposition, 86: crystallization chamber, 88: gas transportation chamber for oxide removal, 90: gas transportation chamber for p⁺-type Si coating (epitaxy). and 100: gas transportation chamber for n⁺-type Si coating (diffusion or epitaxy)

The substrate 96 completely coated with the semiconductor layer system can then be taken out of the chamber through the lock for further processing. Using this arrangement, a system may be constructed allowing the deposition of the complete semiconductor system in a continuous process inside a single chamber purged with inert gas.

1. A method for coating and/or treating a surface of a substrate by applying to the surface a gas containing coat-forming particles necessary for coating being deposited on and/or reacting with the surface,
wherein the gas is separated out into partial flows being tuned with respect to their particle concentrations and/or dwell time on the surface and/or directly in an area of the surface and/or directly adjacent to the surface of the substrate in such a way that equal amounts of particles are deposited and/or react per surface unit and per time unit.

2. A method according to claim 1,
wherein the dwell time is tuned by means of a relative movement and/or speed between the surface and sources emitting the partial flows.

3. A method according to claim 1,
wherein the sources are aligned with the surface such that the partial flows rise vertically or substantially vertically to reach the surface.

4. A method according to claim 1,
wherein the partial flows are emitted to the surface through a plurality of sources having between them sinks for gas having reacted with and/or having been applied to the substrate.

5. A method according to claim 1,
wherein the substrate is heated from a surface facing away from the gas.

6. A method according to claim 4,
wherein the sources and/or sinks are arranged regularly across the surface.

7. A method according to claim 4,
wherein the sources and/or sinks are arranged regularly across an area being at least equal to a vertical projection of the surface of the substrate.

8. A method according to claim 1,
wherein for removing an oxide layer such as a silicon dioxide layer an H₂O/HF mixture is passed across the oxide layer at a temperature T where room temperature ≦T≦300° C., and in particular 50° C.≦T≦100° C.

9. An apparatus for coating and/or treating a surface of a substrate, in particular in a CVD process, by applying to the surface a gas containing coat-forming particles necessary for coating, comprising a plurality of sources emitting the gas as well as a plurality of sinks extracting gas that has reacted with and/or been applied to the substrate
wherein the surface (32) of the substrate (30) is arranged above the sources (14, 16, 18, 20, 46, 48, 50, 74, 76) and the sinks (22, 24, 26, 28, 52, 54, 62) and at least the sources are arranged in a regular pattern in an area defined by a vertical projection of the surface of the substrate.

10. An apparatus according to claim 9,
wherein the sinks (22, 24, 26, 28, 52, 54) are arranged in a regular pattern on an area surrounding the vertical projection (34) of the substrate and/or arranged in a regular pattern between the sources (14, 16, 18, 20, 46, 48, 50).

11. An apparatus according to claim 9,
wherein the sources (14, 16, 18, 20, 46, 48, 50, 74, 76) and the sinks (22, 24, 26, 28, 52, 54, 62) form a gas distribution system (12) whose surface extension is at least equal or substantially at least equal to the surface (34) of the substrate (30).

12. An apparatus according to claim 9,
wherein the sources (14, 16, 18, 20) comprise openings such as slots or nozzles through which the gas may be applied to the surface (34) of the substrate (30).

13. An apparatus according to claim 9,
wherein the sources (14, 16, 18, 20) or the emission openings, such as slots or nozzles, are arranged in a first plane parallel to the surface (34) of the substrate (30).

14. An apparatus according to claim 9,
wherein the sinks (22, 24, 26, 28) are arranged in a second plane parallel to the surface (34) of the substrate (30).

15. An apparatus according to claims 13 and 14
wherein the first and second surfaces are at a distance from each other, the first plane in particular being closer to the surface than the second plane.

16. An apparatus according to claim 9,
wherein the sources (14, 16, 18, 20, 74, 76) comprise openings such as slots or nozzles leading to a space (58) containing a uniformly distributed gas.

17. An apparatus according to claim 16,
wherein the space comprises a plurality of gas distribution pipes (46, 48, 50) running parallel to one another.

18. An apparatus according to claim 9,
wherein a plurality of sources, or their nozzles or openings or slots, are arranged on a straight line, with a plurality of straight lines being in a parallel orientation.

19. An apparatus according to claim 9,
wherein the gas distribution system (46, 48, 50, 52, 54) is arranged inside a reactor chamber sealed off or defined by the surface (34) of the substrate (30).

20. An apparats according to claim 9,
wherein the substrate (30) can be transported to or aligned on the reaction chamber (56) by means of guide rails (70, 72).

21. An apparatus according to claim 9,
wherein a heat source is arranged on a surface (42) of the substrate (30) facing away from the gas distribution system.

22. An apparatus according to claim 9,
wherein a plurality of reaction chambers (80, 82, 84, 86, 88, 90, 92) are arranged in a chamber arrangement (78) which may be purged by an inert gas.

23. An apparatus according to claim 22,
wherein each reaction chamber (80, 82, 84, 86, 88, 90, 92) is able to be closed successively by the substrate (30) or its surface (34).

24. An apparatus according to claim 22,
wherein a variety of gases may be applied to the reaction chambers (80, 82, 84, 86, 88, 90, 92) arranged in the chamber arrangement (78).

25. An apparatus according to claim 22,
wherein the chamber arrangement (78) is a continuous processing arrangement whose reaction chambers (80, 82, 84, 86, 88, 90, 92) may be seated one after the other using the substrate or its surface, for successively coating or treating the surface (34) of the substrate (30).
